(19) United States
(12) Patent Application Publication
(10) Pub. No.: US 2008/0014351 A1
(43) Pub. Date: Jan. 17, 2008

(54) Film forming system, method of operating the same, and storage medium for executing the method

(76) Inventor: Hisashi Inoue, Nirasaki-Shi (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 11/645,799

(22) Filed: Dec. 27, 2006

(30) Foreign Application Priority Data
Dec. 28, 2005 (JP) 2005-379163
Oct. 31, 2006 (JP) 2006-296574

(51) Int. Cl. C23C 16/00; B05C 11/00

(52) U.S. Cl. 427/255.28; 118/708

(57) ABSTRACT

After depositing silicon nitride films on substrates held by a wafer boat in a reaction vessel and subsequently unloading the wafer boat from the reaction vessel, during a time frame from at a point of time when the wafer boat starts to be loaded into the reaction vessel to a point of time when the loading and unloading port of the reaction vessel is closed when the wafer boat holding unprocessed wafers to be processed next is loaded into the reaction vessel, the set temperature of the heaters for heating the reaction vessel are continuously raised. Thereby, temperature drop of the inner wall of the reaction vessel due to loading of a cold wafer boat is prevented, and as a result, unexpected peel-off of reaction products or reaction by-products adhering to the inner wall of the reaction vessel is prevented and contamination of unprocessed wafers by the peeled-off pieces is prevented.

### TECHNICAL FIELD

The present invention relates to a technique for, in a film forming system for forming a silicon nitride film, suppressing particle generation due to peel-off of a film adhered to the inside of a reaction vessel.

### BACKGROUND ART

Semiconductor device manufacturing processes include a process of forming a silicon nitride film (Si₃N₄ Film (hereinafter referred to as “SiN film”)) on the surface of a substrate such as a semiconductor wafer ((hereinafter referred to as “wafer”). The process is typically performed by a batch-type, heat treatment system having a vertical quartz reaction vessel heated by a heater surrounding the vessel. A wafer holder holding thereon wafers W at multiple levels is loaded into the heated reaction vessel, the interior of the reaction vessel is maintained at a predetermined pressure, and gases necessary for film formation are supplied into the reaction vessel, thereby a SiN film is formed on each wafer W by CVD (chemical vapor deposition).

When a SiN film forming process is carried out in the film forming system, films of main products and by-products of the SiN film forming reaction are deposited on the inner wall of the reaction vessel and the wafer holder. If the film thickness is increased to exceed a predetermined value by repeating the film forming process, when heating the interior of the reaction vessel, an ineligible amount of unnecessary gases are generated from the deposited film, and it is highly possible that cracks are formed in the films and the films are thus peeled off to generate particles. In order to avoid this, a purging operation is performed every time when the film forming process is completed.

In general, the purging operation is performed after the wafer holder holding processed wafers W is unloaded from the reaction vessel and before the wafer holder holding unprocessed wafers W to be processed next is loaded into the reaction vessel again. The purging operation is performed by loading the wafer holder, which is empty or holding no wafers, into the reaction vessel, maintaining the interior of the reaction vessel at a predetermined pressure and a predetermined temperature, and conducting rapid cooling, evacuating or heating of the interior of the reaction vessel while supplying a purge gas such as nitrogen (N₂) gas into the reaction vessel. Specifically, the surface part of the film adhered to the inside of the reaction vessel which is ready to peel off is forcibly removed, so that unexpected peel-off of the film during the film forming process is effectively prevented, and generation of gases originated from the adhering film is reduced.

Even if the foregoing purging operation is performed, particles due to peel-off of the film may possibly be generated. For example, when the wafer holder which is cold is loaded into the reaction vessel, or when the temperature in the reaction vessel is lowered from the process temperature to the unloading temperature at which the wafer holder is unloaded from the reaction vessel, it is highly possible that cracks are formed in the film due to lowering of the atmospheric temperature in the reaction vessel and resultant shrinkage of the film, and that the film thus peels off. That is, it is highly possible that particles are generated in the reaction vessel when loading or unloading. Note that, with the prior art, as the set temperature of the heater is maintained constant when the wafer holder is being loaded, the temperature of the inner wall of the reaction vessel is unavoidably lowered when the wafer holder, holding cold wafers, whose temperature is lower than the temperature in the furnace.

There has been known a technique for removing particles generated due to the foregoing reason that jets N₂ gas toward a wafer holder from an injector disposed in a loading area provided below a reaction vessel to remove particles adhering to the surfaces of wafers. Further, there has been known a technique that evacuates the interior of a reaction vessel through an exhaust tube connected to an upper portion of the reaction vessel to discharge particles from the reaction vessel when a wafer holder is loaded and unloaded into and from the reaction vessel.

Even if the above countermeasures are taken, it is not possible to completely prevent adhesion of particles onto wafers. If particles adhere to the surface of a wafer when loading, a SiN film is formed on those particles. Thus, the product yield may possibly be lowered if miniturization of elements progresses in the future.

JP59-175719A discloses a technique that raises the set temperature of the furnace throat area up to a value higher than the heat-treatment target temperature when a part of a boat holding semiconductor substrate being loaded into a furnace (reaction vessel) comes to the soaking area of the furnace, and thereafter lowers the set temperature down to the heat-treatment target temperature, thereby avoiding excessive or insufficient heating of the semiconductor substrates depending on their respective locations in the furnace. The technique disclosed herein focuses only on the heat history of the semiconductor substrates and allows temporary temperature depression of the furnace wall, and thus can not solve the foregoing problem.

### DISCLOSURE OF THE INVENTION

The present invention has been made in view of the foregoing circumstances, and it is the object of the present invention to provide a technique that can suppress generation of particles derived from adhering matters on a reaction vessel when forming a silicon nitride film on substrates.

In order to achieve the above objective, the present invention provides a method of operating a film forming system, the system including a reaction vessel adapted to accommodate a substrate holder that holds substrates while they are aligned, a heater that heats the reaction vessel, a controller that controls the heater such that temperature of the reaction vessel coincides with a predetermined set temperature, the method including: a film forming step that supplies a process gas into the reaction vessel accommodating the substrate holder holding substrates and heats the reaction vessel by means of the heater, thereby to form a silicon nitride film on each of the substrates; an unloading step, performed after the film forming step, that unloads the substrate holder holding the substrates, on each of which a silicon nitride film has been formed, from the reaction vessel through a loading and unloading port provided at the reaction vessel; and a loading step, performed after the unloading step, that loads the substrate holder holding unprocessed substrates into the reaction vessel and closes the loading and unloading port, wherein the loading step is performed with the set temperature being raised at least during a time frame from a point of time when the substrate holder starts to be loaded into the reaction vessel to a point of time when the loading and unloading port is closed.

The present invention also provides a storage medium storing a computer program for carrying out the above method.

The present invention also provides a film forming system for forming a silicon nitride film on substrates, which includes: a reaction vessel adapted to accommodate a substrate holder that holds substrates while they are aligned; a heater that heats the reaction vessel; and a controller that controls the heater such that temperature of the reaction vessel coincides with a predetermined set temperature, wherein the set temperature is set such that the set temperature raises at least during a time frame from a point of time when the substrate holder starts to be loaded into the reaction vessel to a point of time when the loading and unloading port is closed.

Between the unloading step and the loading step, the loading and unloading port may be closed and the temperature of the reaction vessel may be lowered rapidly to forcibly peel off a silicon nitride film adhering to the inside of the reaction tube. The lowering of the temperature may be performed by supplying a cooling gas into the reaction vessel. The cooling gas may be a purge gas, or a cool gas such as air exclusively used for the cooling operation. It is preferable that the temperature of the reaction vessel is raised before rapidly lowering the temperature of the reaction vessel.

### BRIEF DESCRIPTION OF DRAWINGS

FIG. 1 is a vertical cross-sectional view of a film forming system in one example for executing a film forming method according to the present invention.

FIG. 2 is a block diagram showing the structure of a temperature control system of the film forming system.

FIG. 3 is a graph showing set temperatures of the interior of a reaction vessel stored in a controller.

FIG. 4 is a process chart for explaining each process step of a film forming process.

FIG. 5 is a graph showing the relationship between the set temperatures of the interior of a reaction vessel and actual temperatures of an inner wall of the reaction vessel.

FIG. 6 is a graph showing set temperatures in an experiment.

FIG. 7 is a graph showing the number and the sizes of particles adhered to a substrate in the experiment.

### BEST MODE FOR CARRYING OUT THE INVENTION

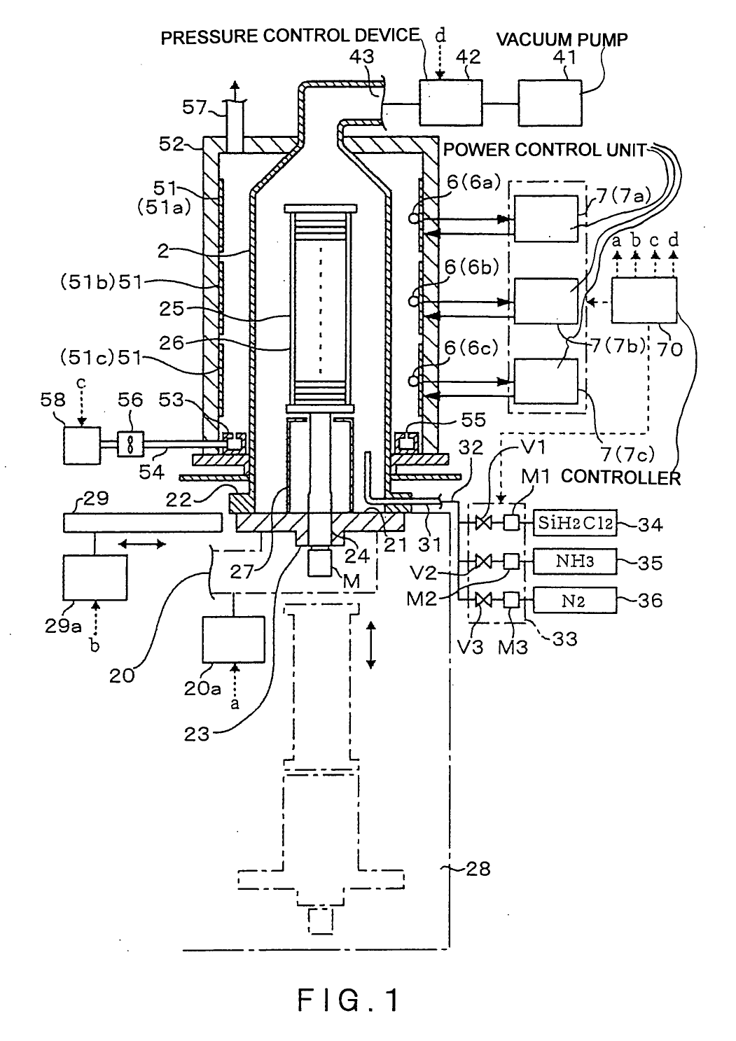

First, the structure of a film forming system is described. FIG. 1 shows a batch-type, low-pressure CVD system, in which reference sign 2 denotes a cylindrical reaction vessel 2 made of quartz whose center axis is oriented to the vertical direction. The reaction vessel 2 has, at its lower end, an opening 21 serving as a loading and unloading port (furnace throat). The reaction vessel 2 has an integrally-formed flange 22 at the periphery of the opening 21. A first lid 23 made of quartz is disposed below the reaction vessel 2. The first lid 23 is raised by means of a boat elevator 20 having an elevating mechanism 20a to be brought into contact with the lower surface of the flange 22 to close the opening 22 in airtight fashion; and is lowered to open the opening 21. A rotary shaft 24 passes through the center portion of the first lid 23. A wafer boat 25 which is a substrate holder is mounted to the upper end of the rotary shaft 24.

The wafer boat 24 has three or more, e.g., four, pillars 26. Plural grooves or slots are formed in each pillar 26 to support plural (125 in the illustrated embodiment) wafers W (substrates) at multiple levels. In processing, plural dummy wafers are held in upper and lower end region of the wafer boat 24 and product wafers are held in a region between the upper and lower end regions. A motor M that rotates the rotary shaft 24 is connected to the lower end of the rotary shaft 24, and the wafer boat 25 rotates by operating the motor M. A thermal insulation unit 27 is disposed on the lid 23 to surround the rotary shaft 24.

By operating the boat elevator 20, the wafer boat 25 moves vertically between a first position in the reaction vessel 2 (where the first lid 23 closes the opening 21 of the reaction vessel 2) and a second position in an loading area 28 (where transferring of wafers to and from the boat elevator 20 is performed). Disposed below the reaction vessel 2 is a second lid 29 made of quartz, which moves horizontally by means of a driving mechanism 29a to close the opening 21 of the reaction vessel 2 in airtight fashion when the first lid 23 is in the loading area 28. Thus, even when the wafer boat 25 is in the loading area 28, the reaction vessel 2 can be closed in airtight fashion.

An L-shaped injector 31 passes through the flange 22 provided at a lower portion of the reaction vessel to supply wafers W in the reaction vessel 2 with gases. A gas supply pipe 32 has one end connected to the injector 31 and the other end connected through a supply control unit 33 to two film-forming gas sources 34 and 35 and a purge gas source 36, and thus a gas necessary for film formation can be supplied through the gas supply pipe 32 and the injector 31. The supply control unit 33 is composed of a supply control device group including valves V1 to V3, flow rate adjusting devices M1 to M3 and the like.

In the illustrated embodiment, the film forming gas sources 34 and 35 are a SiH₂Cl₂ (dichlorosilane: DCS) gas source and an ammonia (NH₃) gas source, respectively; and the purge gas source 36 is an inert gas (e.g., N₂ gas) source. Note that the purge gas is not limited to an inert gas.

An exhaust port is formed in an upper portion of the reaction vessel 2 to evacuate the interior of the reaction vessel 2. Connected to the exhaust port is an exhaust pipe 43, on which there are provided a vacuum pump 41 serving as an evacuating means capable of evacuating the interior of the reaction vessel 2 to a predetermined degree of vacuum and a pressure control device 42 which may be a butterfly valve for example.

Disposed around the reaction vessel is a heating furnace 52, which includes heaters 51 (51a, 51b, 51c) that heat respective regions of the reaction vessel 2 which are defined by dividing the interior of the reaction vessel 2 into a predetermined number of (e.g., three vertical) regions. The heaters 51 (51a, 51b, 51c) are preferably formed of carbon wires that generate no contaminations and exhibit excellent temperature rising and lowering characteristics, but are not limited thereto. Thermocouples 6 (6a, 6b, 6c), or temperature sensors, are disposed near the heaters 51 (51a, 51b, 51c) to detect the temperatures of the heaters 51 (51a, 51b, 51c), respectively.

Power control units 7 (7a, 7b, 7c) are provided to control calorific values of the heaters 51 (51a, 51b, 51c) independently. Each of the power control units 7 (7a, 7b, 7c) is configured to control electric powers supplied to respective ones of the heaters 51 (51a, 51b, 51c) to control calorific values of respective ones of the heaters 51 (51a, 51b, 51c) based on the set temperature (target temperature) of the inner wall of the reaction vessel 2 and temperatures detected by the thermocouples 6 (6a, 6b, 6c). In detail, actual temperatures of the inner wall of the reaction vessel 2 are detected by the thermocouples 6 (6a, 6b, 6c), and the calorific values of the heaters 51 (51a, 51b, 51c) are controlled based on the deviations between the actual-temperature detection results and the set temperature, set beforehand, of the inner wall of the reaction vessel 2, so that the actual temperatures of the inner wall of the reaction vessel 2 are coincide with the set temperature of the inner wall of the reaction vessel 2. Note that, although the thermocouples are disposed outside the reaction vessel 2, the relationship between the actual temperatures detected by the thermocouples 6 (6a, 6b, 6c) and the actual temperatures of the inner wall of the reaction vessel 2 has been grasped beforehand through experiments, and based on the relationship, the power control units 7 (7a, 7b, 7c) correct the temperature detected by the thermocouples. In this specification, the “set temperature” is of “temperature of the inner wall of the reaction vessel 2” for better understanding of the explanation, but may be, of course, of “atmospheric temperature of the interior of the reaction vessel 2”.

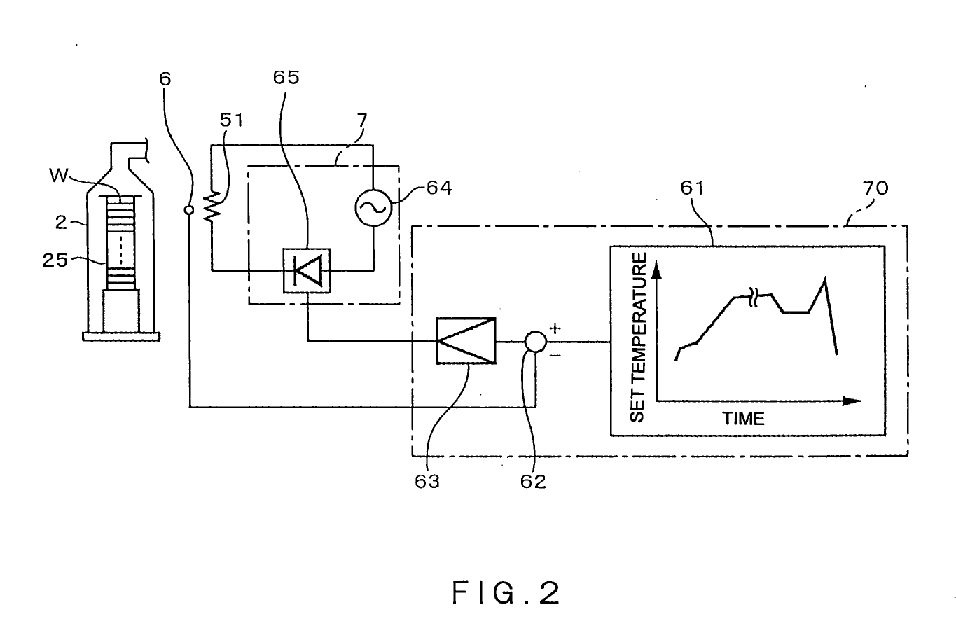

FIG. 2 shows a part of a controller 70 and one of the power control units 7 (7a, 7b, 7c). The controller 70 includes a set temperature output part 61 that outputs the set temperature of the inner wall of the reaction vessel 2 which is set beforehand. In the set temperature output part 61, there is stored a set temperature of the inner wall of the reaction vessel 2 corresponding to a recipe for silicon nitride film (Si₃N₄ film, hereinafter referred to as “SiN film”) formation on the surface of a wafer W employing the foregoing DCS (SiH₂Cl₂) gas and NH₃ gas as film forming gases.

The output of the set temperature output part 61 and the temperature detected by the thermocouple 6 are input to a comparison operating part 62, and the comparison operating part 62 compares them (calculates the difference therebetween). The comparison result (operation signal) which is an output of the comparison operating part 62 is amplified by the amplifier 63, and then is output as a control signal for controlling a switching part 65 which controls electric power supplied from a power source 64 to the heater 51. In the illustrated embodiment, the power control unit 7 (7a, 7b, 7c) is composed of the power source 64 and the switching part 65.

The controller 70 is made of a computer for example, and is configured to control functional elements included in the film forming system such as the elevating mechanism 20a of the boat elevator 20, the driving mechanism 29a for the second lid 29, the power control units 7 for the heaters 51, and the supply control unit 33, the pressure adjusting unit 42 and the air supply system 58. In more detail, the controller 70 includes a storage part storing a sequence program for carrying out a series of process steps, described later, performed in the reaction vessel 2, and means for reading out commands specified by the program to output control signals to the respective functional elements. The program is installed in the controller 70 while it is stored in a storage medium such as a hard disk drive, a flexible disk, a compact disk, a magetooptical disk (MO) or a memory card.

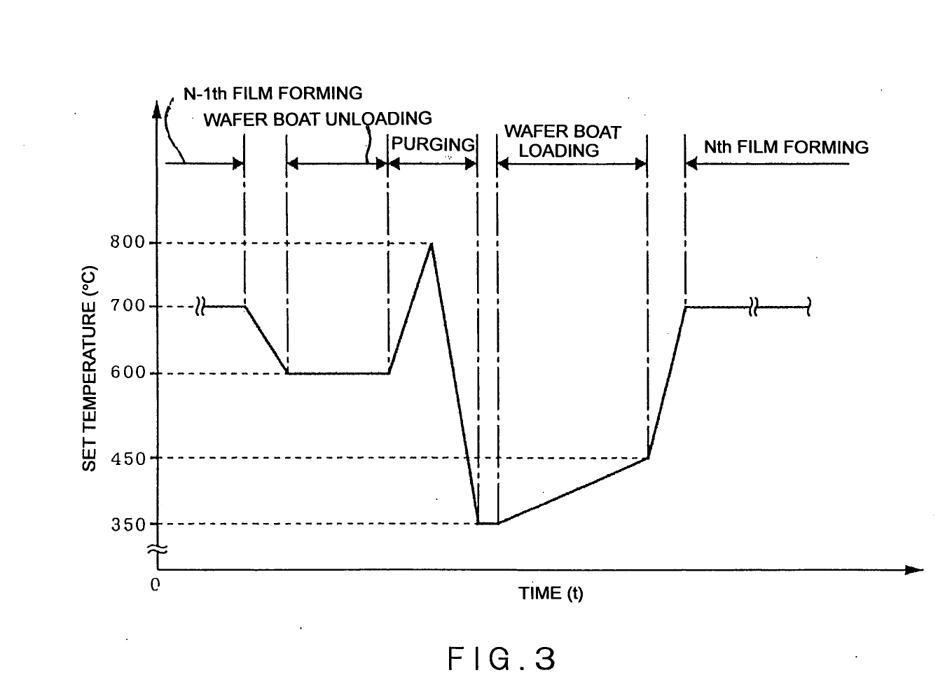

Next, the operation of the foregoing film forming system will be described with reference to FIGS. 3 to 5. Hereinafter, the description is made for the time frame from the completion of the n-1th film forming process to the starting of nth film forming process. As shown in FIG. 3, a predetermined amount of DCS (SiH₂Cl₂) gas and NH₃ gas are supplied into the reaction vessel to perform the n-1th film forming process that forms SiN films on the surfaces of wafers W held by the wafer boat 25. The set temperature of the inside of the reaction vessel 2 during the film forming process is 700° C. After completion of the n-1th film forming process, the temperature of the inside of the reaction vessel 2 is lowered to 600° C. and unloading of the wafer boat 25 is performed.

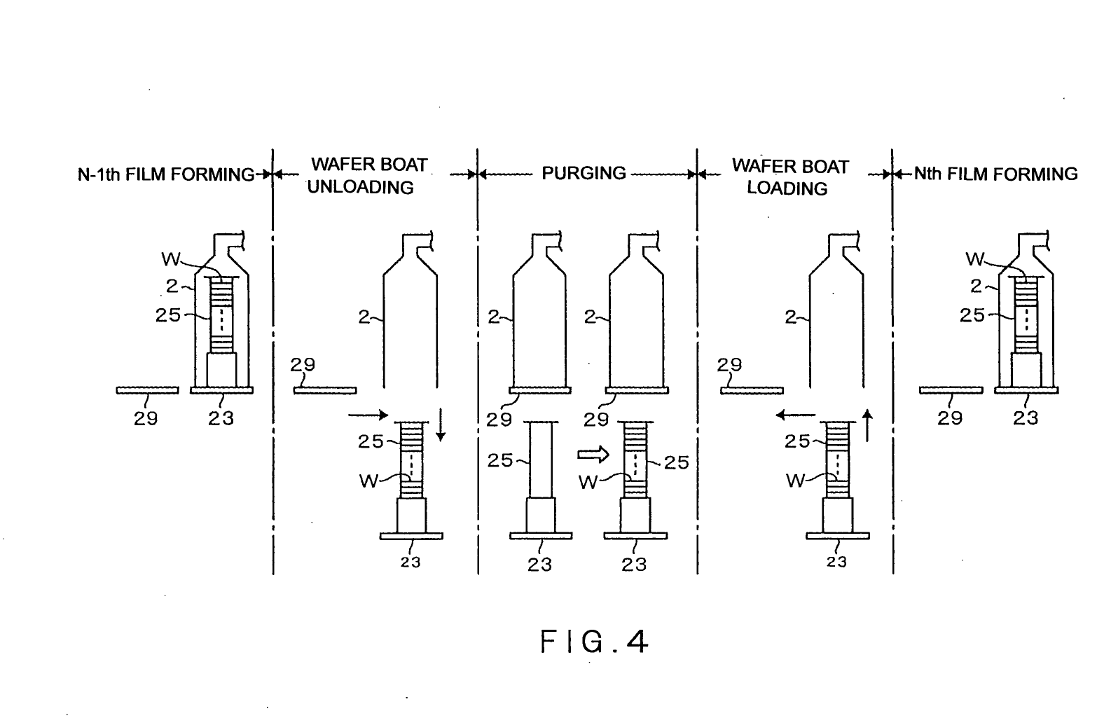

As shown in FIG. 4, unloading of the wafer boat 25 is performed by lowering the wafer boat 25 from the reaction vessel 2 to the loading area 28 by means of the boat elevator 20. Next, the second lid 29 standing-by at its standby area moves horizontally, so that the opening 21 of the reaction vessel 21 is closed again.

Subsequently, the temperature in the reaction vessel 2 is rapidly lowered while a predetermined amount of N₂ gas is supplied from the purge gas source 37 into the reaction vessel 2, so as to perform a purging process (storage purging process) that removes films adhered due to execution of the n-1th film forming process or earlier film forming processes. During the purging process, the set temperature of the inner wall of the reaction vessel 2 is raised from 600° C. to 800° C., and then is rapidly lowered from 800° C. to 350° C. (see FIG. 3). During the purging process, the interior of the reaction vessel 2 is evacuated by means of the vacuum pump 41. When lowering the temperature from 800° C. to 350° C., cool air such as air of 0° C. is supplied from an air supply port 53 into a space between the reaction vessel 2 and the heating furnace 52 while the air thus supplied is discharged through an air discharge path 57. In order to supply the cool air, a cool air source 58 is connected to the air supply port 53 through a supply pipe 54 provided therein with a fan 56. These parts 53, 54, 56 and 58 constitute a cooling gas supply apparatus.

When rapidly cooling the reaction vessel 2 as mentioned above, since a film of reaction main products and reaction by-products rapidly shrinks while the reaction vessel 2 is cooled relatively slowly, cracks are formed in the film. Thereby, the surface part of the film, which may peel off sooner or later if it is left as it is, is forcibly peeled off. Pieces thus peeled off are carried out of the reaction vessel 2 together with the exhaust air flow.

During the purging process for the interior of the reaction vessel 2, wafers W having been processed by the n-1th film forming process are removed from the wafer boat 25 unloaded into the loading area, and wafers to be processed by the nth film forming process are then placed on the wafer boat 25. After completion of the purging process, the second lid 29 hermetically closing the opening 21 of the reaction vessel 2 is moved to its standby area. Thereafter, the wafer boat 25 is raised to be loaded into the reaction vessel 2, and the opening 21 of the reaction vessel 2 is hermetically closed by the first lid 23. During the time frame from the point of time when the wafer boat 23 starts to be loaded into the reaction vessel 2 to the point of time when the opening 21 of the reaction vessel 2 is hermetically closed, the set temperature of the inner wall of the reaction vessel is raised from 350° C. to 450° C. That is, the loading of the wafer boat 25 is performed while the set temperature of the inner wall of the reaction vessel 2 is being raised. The set temperature raising rate during the loading of the wafer boat 25 is 2° C./min, for example.

The wafer boat 25 and the heat insulating unit 27 have been placed outside the reaction vessel 2, and thus the temperatures thereof have been lowered. In addition, many cold unprocessed wafers W are held by the wafer boat 25. Thus, when the upper end portion of the wafer boat 25 enters the interior of the reaction vessel 2, the reaction vessel 2 is cooled through the atmosphere in the reaction vessel, and further, the heaters 51 are cooled through the atmosphere between the reaction vessel and the heaters 51. At this time, if the loading operation is performed while the set temperature is not being raised, temperature drop may occur, and thus a film of main reaction products or reaction by-products may further peel off to contaminate the unprocessed wafers W. However, with this embodiment, since the set temperature is being raised when the upper end portion of the wafer boat 25 enters the interior of the reaction vessel 2, the temperature of the reaction vessel 2 is not lowered so that further peel-off of the film can be prevented.

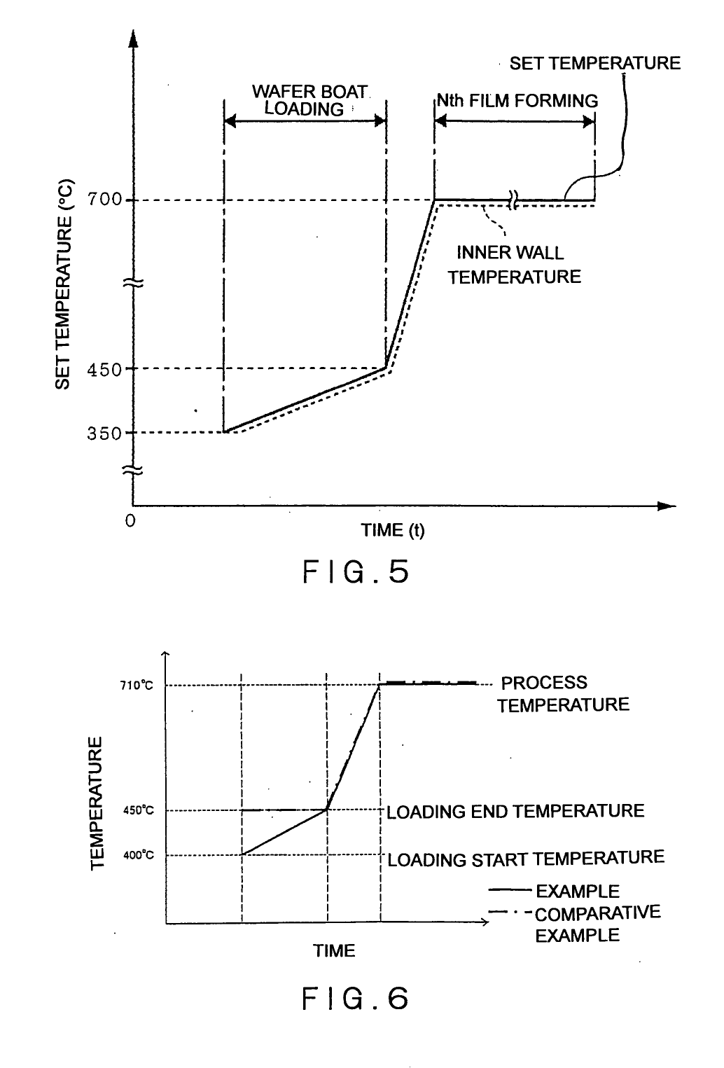

Meanwhile, whether the temperature is lowered or not when loading the wafer boat 25 also depends on the heat capacities of the reaction vessel 2 and the heaters 51, and the temperature of the reaction vessel 2 when the loading starts. If the heat capacities of the reaction vessel 2 and the heaters 51 are relatively small, it is possible that the cooling effect resulted from loading of the cold wafer boat 25 exceeds the heating effect of the heater 51 resulted from raising of the set temperature and thus the temperature in the reaction vessel 2 is temporarily lowered when the loading starts. For example, in a case where the temperature of the reaction vessel 2 is relatively high, in other words, a relatively large temperature difference exists between the reaction vessel 2 and the wafer boat 25, it is possible that the temperature of the reaction vessel 2 is temporarily lowered when starting loading. If the heat capacities of the reaction vessel 2 and the heaters 51 are relatively large, the cooling effect resulted from loading of the cold wafer boat 25 brings a relatively low influence. Thus, it is preferable that the set temperature at the time when the loading starts be determined considering at least one of the heat capacities of the reaction vessel 2 and the heaters 51. Although the set temperature is 350° C. in the embodiment shown in FIG. 5, it is preferable that the set temperature be lower if the heat capacities are smaller. On the other hand, the set temperature at the time when the loading starts may be lower, if the heat capacities are smaller. Anyway, preferably, the set temperature at the time when the loading starts is set, in view of the foregoing factors, such that the temperature lowering of the inner wall of the reaction vessel 2 due to loading of the wafer boat 25 does not occur or is negligible small.

Note that, during the loading operation, it is not preferable to raise the set temperature at once up to the final value for the loading operation and maintain the set temperature (refer to Comparative Example which will be described later with reference to FIG. 6). Under such a situation, the actual temperature overshoots and thereafter temperature drop occurs, which results in peel-off of the film. On the contrary, if the loading operation is performed while the set temperature is being raised, the actual temperature well traces the target temperature (see broken lines of FIG. 5), and the overshooting does not occur.

After completion of the loading of the wafer boat 25 into the reaction vessel 2, the temperature of the inner wall of the reaction vessel 2 is raised up to a predetermined film-forming temperature, e.g., 700° C., and the nth film forming process is performed. In this way, in the film forming system in the foregoing embodiment, the film forming process and the purging process are sequentially carried out while performing temperature control operation according to the set temperature of the interior of the reaction vessel 2 stored in the set temperature output part 61.

According to the foregoing embodiment, since the wafer boat 25 holding the wafers W is loaded into the reaction vessel 2 while the set temperature of the inner wall of the reaction vessel 2 is being raised, it is not possible that cracks are produced in the silicon nitride film adhered to the inner wall of the reaction vessel 2 due to shrinkage of the film associated with the lowering of its temperature. Thus, it is possible to prevent particles from adhering to the substrates.

In addition, since the silicon film adhering to the inside of the reaction vessel 2 is forcibly peeled off by rapidly lowering the temperature in the reaction vessel 2 before loading of the water boat, adhesion of particles to the wafer W surfaces before film formation can be prevented more effectively. In this case, it is preferable to once raise the temperature in the reaction vessel, and the peak value of that raised temperature is preferably higher than the process temperature.

In the foregoing embodiment, the actual temperature of the inner wall of the reaction vessel 2 is also raised by raising the set temperature thereof. However, the present invention is not limited thereto. It should be noted that it is sufficient if lowering of the actual temperature of the inner wall of the reaction vessel does not occur or is negligible small. The point of time when the set temperature starts raising may be a point of time when the second lid 29 opens after completion of the purging process, or may be a point of time immediately before the upper end of the wafer boat 25 enters the reaction vessel 2.

In the foregoing embodiment, DCS (SiH₂Cl₂) gas and NH₃ gas are used as film-forming gases for forming a SiN film on the surface of each wafer W, but the film-forming gases are not limited thereto. Si₂Cl₆ (HCD) gas and NH₃ gas, or bistertiarybutylaminosilane (BTBAS) and NH₃ gas are may be used.

### EXAMPLE

Next, experiments, which were conducted to confirm the advantageous effects of the present invention, will be described.

### Example

The experiment employed a film forming system of the same type as shown in FIG. 1 which had been used to perform the SiN film forming process repeatedly and in which a film of a predetermined accumulated thickness had been adhered to the inside of a reaction vessel 2. First, with the use of the film forming system, a wafer boat 25 holding wafers W was loaded into a reaction vessel 2, and then silicon nitride films were formed on the surfaces of the wafers W. The set temperature of the inner wall of the reaction vessel 2 at the point of time when loading of the wafer boat 25 into the reaction vessel 2 started was 400° C., and the set temperature of the inner wall of the reaction vessel 2 at the point of time when an opening of the reaction vessel 2 was hermetically closed by a first lid 23 was 450° C. The temperature raising rate between these points of time was 3° C./min. The set temperature of the inner wall of the reaction vessel 2 during the process was 710° C., and the set pressure in the reaction vessel was 33 Pa (0.25 Torr). During the process, DCS (SiH₂Cl₂) gas and NH3 gas were used as film forming gases, and the flow rates of DCS (SiH₂Cl₂) gas and NH₃ gas were 120 sccm and 1200 sccm, respectively. In FIG. 6, the change in the set temperature in Example is shown by solid lines.

### Comparative Example

The film forming process was carried out under the same process conditions except that the set temperature during the time frame from the point of time when loading of the wafer boat 25 into the reaction vessel 2 started to the point of time at the point of time when an opening of the reaction vessel 2 was hermetically closed was kept constant at 450° C. In FIG. 6, the change in the set temperature in Comparative Example is shown by solid lines.

(Observation Method)

After completion of each film forming process, the wafer boat 25 was unloaded from the reaction vessel, and then one (TOP) of the wafers held in the upper region of the wafer boat 25, one (CTR) of the wafers held in the middle region of the wafer boat 25, and one (BTM) of the wafers held in the lower region of the wafer boat 25 were removed from the wafer boat 25; each of the removed wafers was exposed to a light and particles adhering to the wafer were observed. Thereafter, film forming processes were further performed to the wafers under the conditions which were identical to those for Examples and Comparative Examples, respectively; and after each film forming process, the second particle observation was performed in the aforementioned manner.

(Results and Consideration)

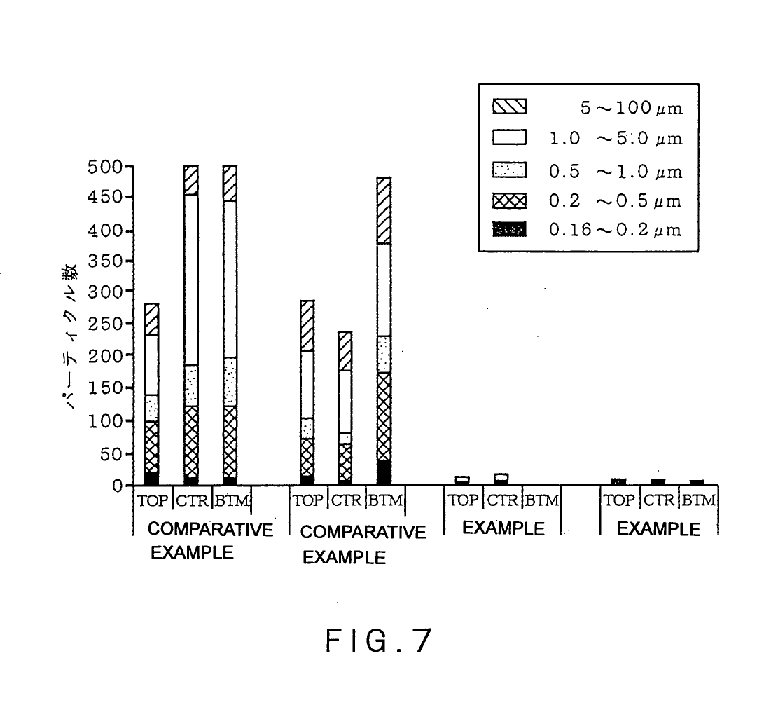

FIG. 7 shows the results of Examples and Comparative Examples. As shown in FIG. 7, the number of particles adhering to each wafer (TOP, CTR, BTM) was drastically reduced in Example, as compared with Comparative Example. From this results, it can be seen that peeling-off of a silicon nitride film adhering to the inner wall of the reaction vessel 2 can be suppressed by loading wafer boat into the reaction vessel 2 while raising the set temperature of the inner wall of the reaction vessel to prevent the temperature drop of the inner wall of the reaction vessel 2.

1. A method of operating a film forming system, the system including a reaction vessel adapted to accommodate a substrate holder that holds substrates while they are aligned, a heater that heats the reaction vessel, a controller that controls the heater such that temperature of the reaction vessel coincides with a predetermined set temperature, said method comprising:
a film forming step that supplies a process gas into the reaction vessel accommodating the substrate holder holding substrates and heats the reaction vessel by means of the heater, thereby to form a silicon nitride film on each of the substrates;
an unloading step, performed after the film forming step, that unloads the substrate holder holding the substrates, on each of which a silicon nitride film has been formed, from the reaction vessel through a loading and unloading port provided at the reaction vessel; and
a loading step, performed after the unloading step, that loads the substrate holder holding unprocessed substrates into the reaction vessel and closes the loading and unloading port,
wherein the loading step is performed with the set temperature being raised at least during a time frame from a point of time when the substrate holder starts to be loaded into the reaction vessel to a point of time when the loading and unloading port is closed.

2. The method according to claim 1, further comprising a forced peeling step, performed between the unloading step and the loading step, that closes the loading and unloading port and rapidly lowers the temperature of the reaction vessel, thereby to forcibly peel off a silicon nitride film or its reaction by-products adhering to an inner surface of the reaction vessel.

3. The method according to claim 2, wherein the temperature of the reaction vessel is raised before rapidly lowering the temperature of the reaction vessel.

4. A film forming system for forming a silicon nitride film on substrates, comprising:
a reaction vessel adapted to accommodate a substrate holder that holds substrates while they are aligned;
a heater that heats the reaction vessel; and
a controller that controls the heater such that temperature of the reaction vessel coincides with a predetermined set temperature,
wherein the set temperature is set such that the set temperature raises at least during a time frame from a point of time when the substrate holder starts to be loaded into the reaction vessel to a point of time when the loading and unloading port is closed.

5. The film forming system according to claim 4, further comprising a gas supply apparatus that supplies a cooling gas for rapidly lowering the temperature of the reaction vessel,
wherein the controller is configured to control the gas supply apparatus to rapidly lower temperature in the reaction vessel while the loading and unloading port for the substrate holder is closed so that a silicon nitride film adhered to an inner wall of the reaction vessel is forcibly peeled off, after the substrate holder holding substrates on each of which a silicon nitride film has been formed is unloaded from the reaction vessel.

6. The film forming system according to claim 4, wherein the controller is configured to control the heater such that temperature of the reaction vessel is raised before the temperature in the reaction vessel is rapidly lowered.

7. A storage medium storing a computer program for controlling a film forming system, wherein upon execution of the program a control computer controls the film forming system to perform a predetermined method,
wherein the predetermined method is a method defined in claim 1.

8. A storage medium storing a computer program for controlling a film forming system, wherein upon execution of the program a control computer controls the film forming system to perform a predetermined method,
wherein the predetermined method is a method defined in claim 2.

9. A storage medium storing a computer program for controlling a film forming system, wherein upon execution of the program a control computer controls the film forming system to perform a predetermined method,
wherein the predetermined method is a method defined in claim 3.
